(19) United States
(12) Patent Application Publication
(10) Pub. No.: US 2009/0219687 A1
(43) Pub. Date: Sep. 3, 2009

(54) Memory heat-dissipating mechanism

(76) Inventor: Jui-Nan Lin, Banciao City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/073,182

(22) Filed: Mar. 3, 2008

(51) Int. Cl. H05K 7/20

(52) U.S. Cl. 361/695; 361/704

(57) ABSTRACT

A memory heat-dissipating mechanism includes: at least two memory devices, a heat dissipater, and a plurality of screw components. Each memory device comprises two inter-cooperating heat-dissipating pieces and a memory module sandwiched between the two heat-dissipating pieces. The heat-dissipating pieces of each memory device are provided thereon with locking holes. The heat dissipater comprises a base, a plurality of heat-dissipating pillars extending from the base, and a plurality of fixing slots. Each fixing slot corresponds to the locking hole of each memory device. The top surface of the heat-dissipating piece of each memory device abuts against a bottom surface of the base of the heat dissipater. The screw components penetrate the fixing slots of the heat dissipater respectively to be screwed into the locking holes of corresponding memory device, thereby secure the heat dissipater. Via this arrangement, the present invention can dissipate the heat of the memory module.

### BACKGROUND OF THE INVENTION

1. Field of the Invention

The present invention is related to a memory heat-dissipating mechanism, and in particular to a memory heat-dissipating mechanism for dissipating the heat of a memory module and avoiding from occupying the distance between left and right sides of adjacent memory modules.

2. Description of Related Art

With the continuous progress of modern computer technology, the computers are gradually developed to have powerful operation function and high operation speed. Further, with computer design field gearing towards high speed and high frequency, it is necessary to dissipate the heat of CPU on a main board by means of a heat-dissipating device. On the other hand, since the memory capacity of a memory module is expanding and operates at a high speed with the CPU, the heat generated by the memory module continue to increase, which may affect the CPU performance. Furthermore, if the heat cannot be dissipated efficiently, the memory module life span would shorten and eventually fail.

Therefore, in order to solve the problem of memory module heat generation, an air-cooling heat sink or water-cooling heat-dissipating device is used to dissipate the heat of the memory module. For example, Taiwan Patent Publication No. M323066 (Application No. 096209265) discloses a modularized water-cooling heat-dissipating device, in which a fixed support is arranged on a heat-generating element (e.g. memory module) on a main board. The fixed support is connected to a water pump having inlet pipe and outlet pipe, and a water cooler having inlet pipe and outlet pipe, respectively. Connecting pipes are provided to link the pipes of the water pump and the water cooler with the heat-dissipating module. Via this arrangement, the heat generated by the memory module can be transferred indirectly to the water and dissipated.

Although the above-mentioned patent can dissipate the heat in practice, its volume is bulky, which occupies a lot of space within the computer and thus makes difficult the arrangement of other electronic elements within the computer.

Therefore, in order to avoid the drawback that the water-cooling heat-dissipating device occupies a lot of internal space, an air-cooling heat sink is used. For example, Taiwan Patent Publication No. M321118 (Application No. 095220519) discloses a heat sink for a memory module, in which a plurality of heat-dissipating pieces are positioned on left and right sides of the memory module via a frame respectively. The base of the heat-dissipating piece abuts against the memory module. The base is provided with a plurality of upright fins extending transversely away from the memory module. Via this arrangement, the heat dissipation of the memory module can be achieved by means of air circulation.

However, the main board is usually designed in such a manner that four memory modules can be inserted thereon. The distance between adjacent memory modules is made according to the standard specification of the manufacturer. In the above-mentioned patent, the heat-dissipating pieces on both sides of the memory model are provided with a plurality of transversely-extending fins. In practice, all of the fins have a certain extending distance, which will occupy the space for the adjacent memory modules on the main board. Therefore, the heat sink disclosed in the above-mentioned patent merely allows one or two memory modules to be inserted on the main board, but it cannot allow more than three memory modules to be inserted thereon. Even, if a main board of different specification is used, only one memory module can be inserted. Thus, although the heat sink disclosed in the above-mentioned patent can dissipate the heat, it also has the drawback of occupying space.

Consequently, because of the above technical limitations, the inventor strives via real world experience and academic research to develop the present invention, which can effectively improve the limitations described above.

### SUMMARY OF THE INVENTION

The object of the present invention is to provide a memory heat-dissipating mechanism for dissipating the heat of the memory module and avoid from occupying the distance on the outer sides of adjacent memory modules.

For achieving the object described above, the present invention provides a memory heat-dissipating mechanism, which includes: at least two memory devices arranged in parallel with a distance therebetween, each memory device comprising two inter-cooperating heat-dissipating pieces and a memory module sandwiched between the two heat-dissipating pieces, the heat-dissipating pieces of each memory device being provided thereon with locking holes; a heat dissipater mounted on the memory devices, the heat dissipater comprising a base, a plurality of heat-dissipating pillars extending upwards from the base, and a plurality of fixing slots, each fixing slot corresponding to the locking hole of each memory device, a top surface of the heat-dissipating piece of each memory device abutting against a bottom surface of the base of the heat dissipater; and a plurality of screw components penetrating the fixing slots of the heat dissipater respectively to be secured into the locking holes of corresponding memory device.

The present invention has advantageous effects as follows. The heat dissipater having heat-dissipating pillars is mounted on at least two memory devices that are arranged in parallel, thereby utilizing the space above the memory device and achieving the heat dissipation of the memory module by air cooling. In comparison with the conventional art, the present invention avoids from occupying the distance between left and right sides of adjacent memory modules. In this way, the present invention can be applied to the main boards of various specifications, and thus four memory modules can be inserted thereon if desired.

Next, the heat dissipater is provided with fixing slots, so that the position of the heat dissipater can be adjusted to facilitate the alignment with the locking holes of the memory device. In this way, the present invention can be applied to the main board of various specifications.

In order to further understand the characteristics and technical contents of the present invention, the present invention will be explained with reference to the following description and accompanying drawings. However, the drawings are illustrative only and are not used to restrict the scope of the present invention.

### BRIEF DESCRIPTION OF THE DRAWINGS

FIG. 1 is an exploded perspective view of the present invention;

FIG. 2 is an assembled perspective view showing the present invention being mounted on a main board;

FIG. 3 is an exploded perspective view showing another embodiment of the present invention being mounted on the main board; and

FIG. 4 is an assembled perspective view showing the present invention being assembled with a heat-dissipating fan.

### DETAILED DESCRIPTION OF THE PREFERRED EMBODIMENTS

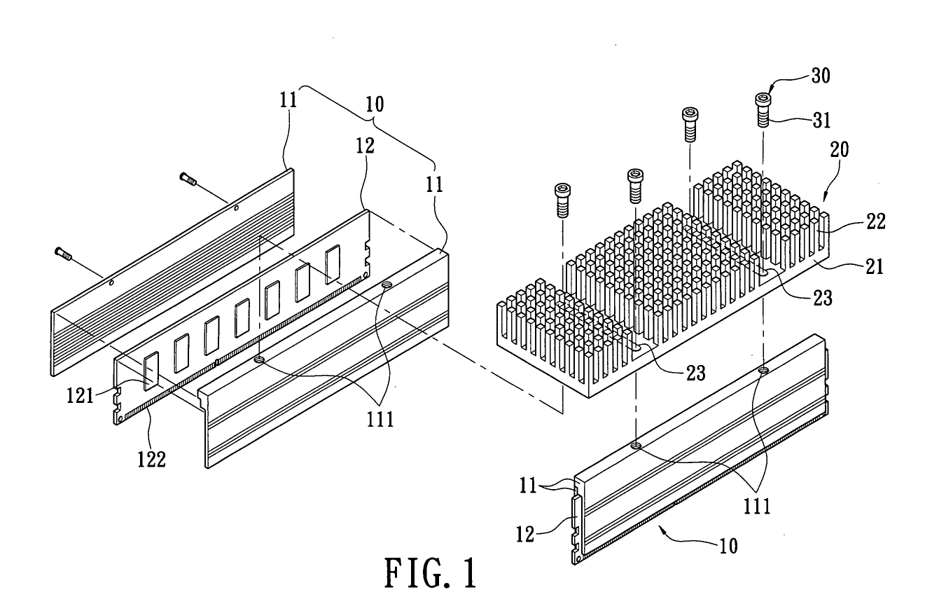

Please refer to FIG. 1. The present invention provides a memory heat-dissipating mechanism, which includes at least two memory devices 10, a heat dissipater 20, and a plurality of screw components 30.

Each memory device 10 comprises two inter-cooperating heat-dissipating pieces 11, and a memory module 12 sandwiched between two heat-dissipating pieces 11. Two heat-dissipating pieces 11 can be made by means of connecting two corresponding portions with each other. Alternatively, one heat-dissipating piece is larger than the other, and both heat-dissipating pieces are connected with each other by means of screw tightening. In the present invention, the way of connecting two heat-dissipating pieces is not limited to any specific form. Two heat-dissipating pieces 11 are used to sandwich and abut against memory chips 121 of memory module 12, so that the heat generated can be transferred to heat-dissipating pieces 11. The top surfaces of heat-dissipating pieces 11 of each memory device 10 are provided with a plurality of locking holes 111, each of which is a screw hole.

Heat dissipater 20 is made of a metallic element having a heat-dissipating effect, which comprises a plate-like base 21, a plurality of heat-dissipating pillars 22, and a plurality of fixing slots 23. Each heat-dissipating pillar 22 extends upwardly from the top surface of base 21. There may be two fixing slots 23 that are spaced apart with a distance therebetween and each passes through the top and bottom surfaces of base 21.

Each screw components 30 can be a bolt. The number of the screws corresponds to the number of locking holes 111 of memory device 10. Each screw component 30 has a threaded portion 31.

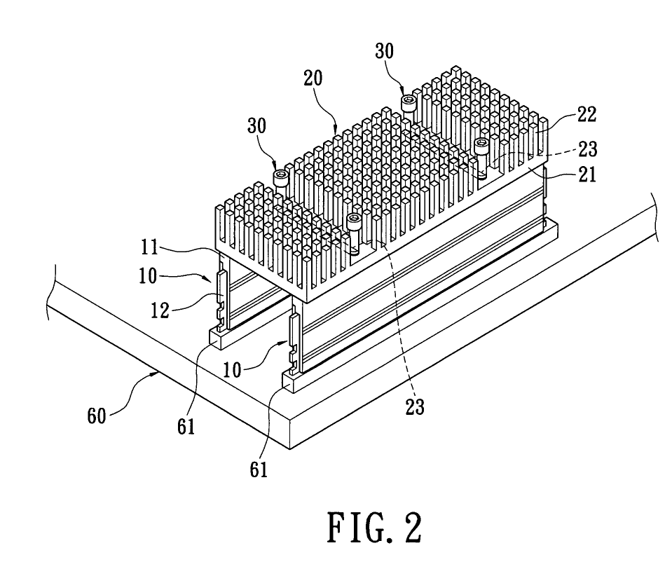

In assembly, please refer to FIGS. 1 and 2, in which two memory devices 10 are used as an example. Memory module 12 of each memory device 10 is inserted onto an electrical connector 61 of a main board 60 of a computer. The two memory devices are arranged in parallel with a distance therebetween, so that pins 122 of each memory module 12 can be inserted into the corresponding electrical connector 61, thereby achieving the electrical connection between each memory module 12 and main board 60.

The heat dissipater 20 is mounted on the two memory devices 10. The top surfaces of heat-dissipating pieces 11 of each memory device 10 abut against the bottom surface of base 21 of heat dissipater 20, so that the heat generated by memory module 12 can be transferred to heat dissipater 20 via heat-dissipating pieces 11. At the same time, each fixing slot 23 of heat-dissipating dissipater 20 corresponds to locking hole 111 of each memory device 10. Screw component 30 penetrates fixing slot 23 of heat dissipater 20 and is secured into locking hole 111 of the corresponding memory device 10. With threaded portion 31 of each screw component 30 penetrating fixing slot 23 and being secured into locking hole 111, heat dissipater 20 can be fixed on the two memory devices 10.

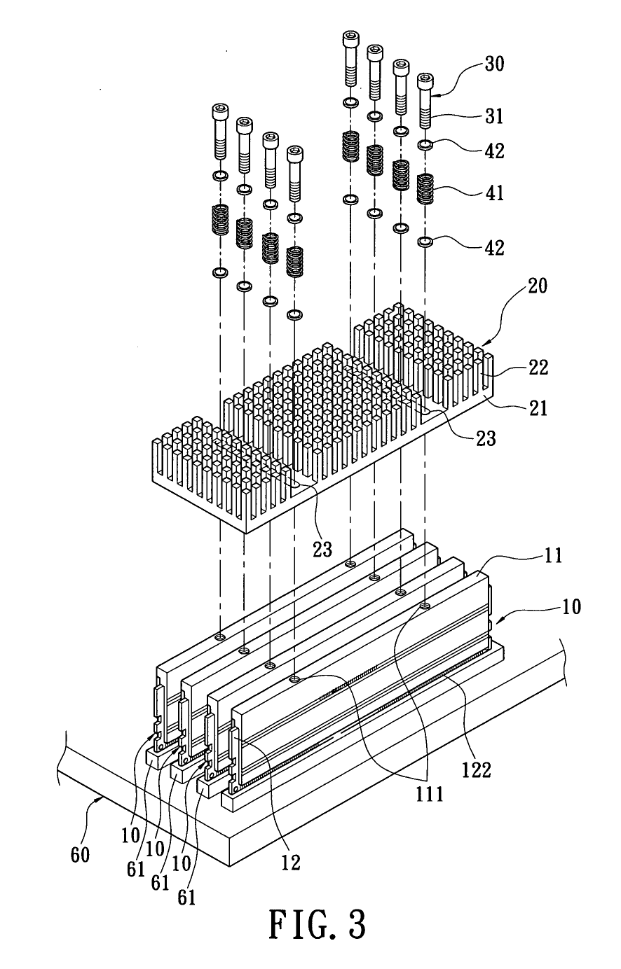

Further, please refer to FIG. 3. In the present embodiment, according to the design of main board 60, four memory devices 10 can be inserted on the main board. Thus, heat dissipater 20 of the present invention can be brought into contact with four memory devices 10. In addition, threaded portion 31 of each screw component 30 penetrates an elastic element 41 and a gasket 42. Elastic element 41 can be a compression spring. Both ends of each elastic element 41 abut against screw component 30 and gasket 42 respectively, so that gasket 42 abuts against the top surface of base 21 of heat dissipater 20. Alternatively, two gaskets 42 are provided on both ends of elastic element 41 respectively. Both ends of elastic element 41 abut elastically against the two gaskets 42 respectively with one of the gaskets 42 abutting against the top surface of base 21 of heat dissipater 20. In this way, when threaded portion 31 of screw component 30 is gradually locked into locking hole 111 of memory device 10, elastic element 41 can be compressed to force gasket 42 on heat dissipater 20, thereby secure heat dissipater 20 in position more firmly.

Especially, it should be noted that since memory device 10 can be inserted on main board 60 of various specifications, while the distance between adjacent electrical connectors 61 of each main board 60 is different, fixing slot 23 of the present invention is designed to facilitate the alignment with locking hole 111 of memory device 10, so that crew component 30 can be locked into locking hole 111 accurately to secure heat dissipater 20 in position. That is to say, fixing slot 23 has a function of adjusting the position of heat dissipater 20.

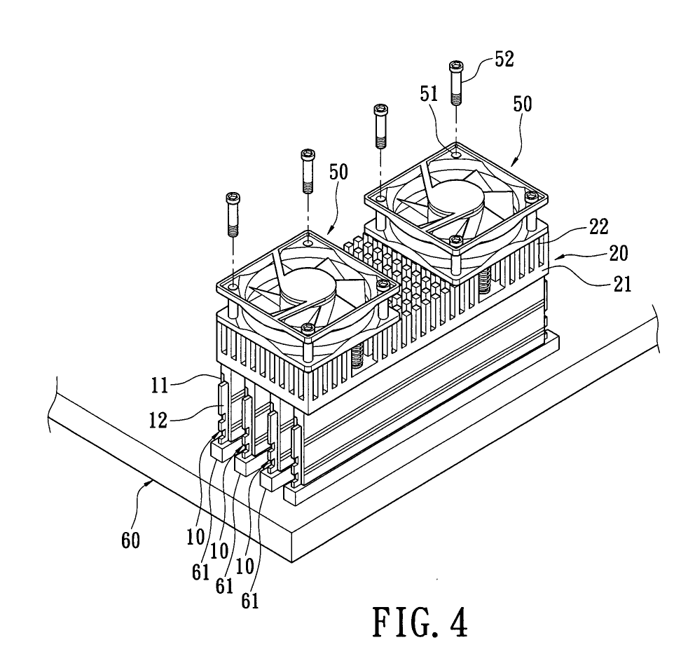

Furthermore, please refer to FIG. 4. At least one heat-dissipating fan 50 can be locked on heat-dissipating pillars 22 of heat dissipater 20. The heat-dissipating fan is fixed by means of locking elements 52 penetrating through holes 51 on four sides of heat-dissipating fan 50 to be locked in the gaps formed between heat-dissipating pillars 22 of heat dissipater 20. With the design of heat-dissipating pillar 22, heat-dissipating fan 50 can be locked easily.

To sum up the above, in the present invention, heat dissipater 20 having heat-dissipating pillars 22 is mounted on at least two memory devices 10 that are arranged in parallel, thereby utilizing the space above memory device 10 and achieving the heat dissipation of the memory module 12 by air cooling. In comparison with the conventional art, the present invention avoids from occupying the space to the outer left and right sides of adjacent memory modules 12. In this way, the present invention can be applied to main boards 60 of various specifications, and thus four memory modules 12 can be inserted thereon if desired.

Next, heat dissipater 20 is provided with fixing slots 23, so that the position of heat dissipater 20 can be adjusted to facilitate the alignment with locking holes 111 of memory device 10. In this way, the present invention can be applied to main boards 60 of various specifications.

Further, heat dissipater 20 is provided thereon with a plurality of heat-dissipating pillars 22 which facilitate heat-dissipating fan 50 to be secured to heat dissipater 20. Thus, in comparison with the conventional heat dissipater having heat-dissipating fins, the present invention eliminates the problem that the heat-dissipating fan cannot be locked to the fins easily.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A memory heat-dissipating mechanism, comprising:
at least two memory devices arranged in parallel with a distance therebetween, each memory device comprising two inter-cooperating heat-dissipating pieces and a memory module sandwiched between the two heat-dissipating pieces, the heat-dissipating pieces of each memory device being provided thereon with locking holes;
a heat dissipater mounted on the memory devices, the heat dissipater comprising a base, a plurality of heat-dissipating pillars extending upwards from the base, and a plurality of fixing slots, each fixing slot corresponding to the locking hole of each memory device, a top surface of the heat-dissipating piece of each memory device abutting against a bottom surface of the base of the heat dissipater; and
a plurality of screw components penetrating the fixing slots of the heat dissipater respectively to secure into the locking holes of the corresponding memory device.

2. The memory heat-dissipating mechanism according to claim 1, wherein the memory module of each memory device is inserted into an electrical connector of a main board.

3. The memory heat-dissipating mechanism according to claim 1, wherein each screw component has a threaded portion, each threaded portion penetrates the corresponding fixing slot to be locked into the locking hole.

4. The memory heat-dissipating mechanism according to claim 3, wherein each threaded portion penetrates an elastic element and a gasket, both ends of the elastic element abut against the screw component and the gasket respectively with the gasket abutting against the top surface of the base of the heat dissipater.

5. The memory heat-dissipating mechanism according to claim 4, wherein each screw component is a bolt, and the elastic element is a compression spring.

6. The memory heat-dissipating mechanism according to claim 3, wherein each threaded portion penetrates an elastic element and two gaskets, both ends of the elastic element abut elastically against the two gaskets respectively with one of the gaskets abutting against the top surface of the base of the heat dissipater.

7. The memory heat-dissipating mechanism according to claim 6, wherein each of the screw components is a bolt, and the elastic element is a compressed spring.

8. The memory heat-dissipating mechanism according to claim 1, wherein at least one heat-dissipating fan is locked to the heat-dissipating pillars of the heat dissipater.

9. The memory heat-dissipating mechanism according to claim 8, wherein the heat-dissipating fan is locked by means of locking elements penetrating through holes of the heat-dissipating fan and being locked into the gaps between the heat-dissipating pillars of the heat dissipater.

10. The memory heat-dissipating mechanism according to claim 1, comprising four memory devices.
